(19) United States
(12) Patent Application Publication
(10) Pub. No.: US 2015/0160142 A1
(43) Pub. Date: Jun. 11, 2015

(54) METHOD AND APPARATUS FOR INCREASING SIGNAL TO NOISE RATIO IN AN NQR SYSTEM

(71) Applicant: R.A. MILLER INDUSTRIES, INC., Grand Haven, MI (US)

(72) Inventor: Paul A. Zank, Brookline, NH (US)

(21) Appl. No.: 14/401,851

(22) PCT Filed: May 24, 2013
(86) PCT No.: PCT/US13/42656

§ 371 Date: Nov. 18, 2014

Related U.S. Application Data
(60) Provisional application No. 61/651,337, filed on May 24, 2012.

(51) Int. Cl. G01N 24/08; G01R 33/56; G01R 33/44

(52) U.S. Cl. CPC G01N 24/084; G01R 33/441; G01R 33/56

(57) ABSTRACT

In a method for increasing signal to noise ratio in a Nuclear Quadrapole Resonance (NQR) system comprising the steps of transmitting in a first and second frequency and listening at a third frequency.

### CROSS-REFERENCE TO RELATED APPLICATIONS

This application claims the benefit of U.S. Provisional Application Ser. No. 61/651,337, filed May 24, 2012, which is incorporated herein in its entirety.

### BACKGROUND OF THE INVENTION

1. Field of the Invention

The present application relates to Nuclear Quadrapole Resonance (NQR) and more particularly to methods and systems for detecting explosives by means of NQR.

2. Brief Description of Prior Developments

A number of methods and systems have been suggested in the prior art by means of which explosives may be detected by means of NQR.

One problem which may still be presented by such NQR methods and systems is that there may be some difficulty in removing the transmitted signal from the returned signal due to the identity of the frequencies of the transmitted and received signals.

A need, therefore, exists for a way to improve signal to noise ratio in NQR systems.

### SUMMARY OF INVENTION

According to the present invention, the signal to noise ratio in an NQR system is improved by pumping two spectral lines at two different frequencies causing a cascading energy event, such that energy is emitted at a lower frequency. For instance assuming that the two frequencies are 3 MHz and 3.3 MHz, then the resultant signal is detected at 1 MHz which offers a significant signal-to-ratio advantage.

### BRIEF DESCRIPTION OF THE DRAWINGS

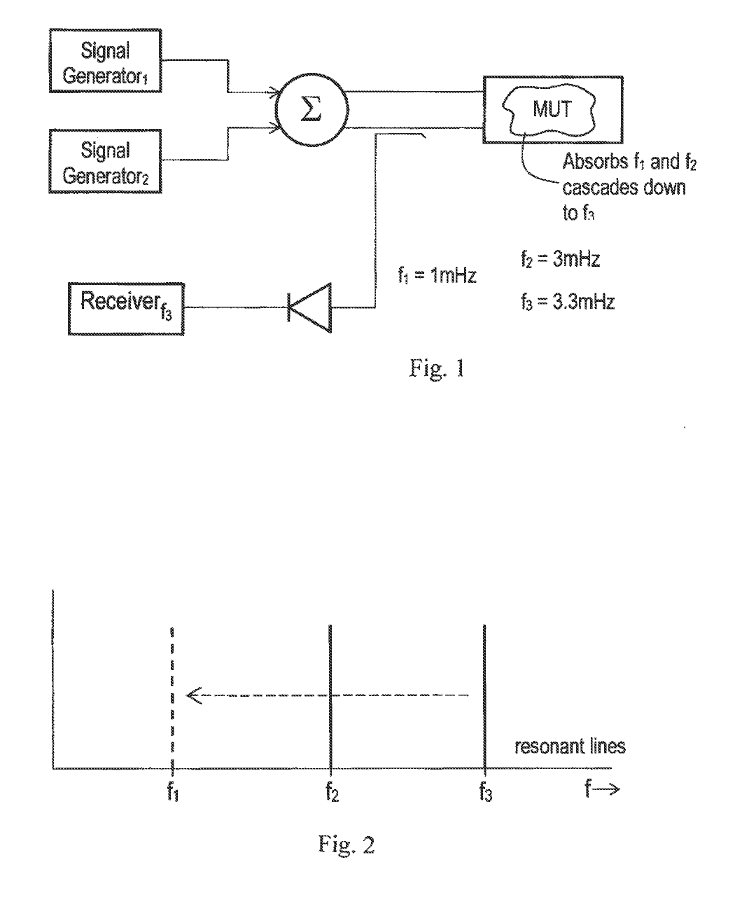

Referring to FIG. 1, an apparatus for carrying out the method of the present invention is shown; and

Referring to FIG. 2, a graph is shown showing two spectral lines a two different frequencies f2 and f3 cascading energy event results so that energy is emitted at a lower frequency f1.

### DETAILED DESCRIPTION OF A PREFERRED EMBODIMENT

The apparatus and method described herein is an improvement of the apparatus and method disclosed in WO 2011/094463, the disclosure of which is incorporated herein by reference. Looking first at FIG. 1, a signal generator Si is configured to transmit a first signal at frequency f₂. Signal generator S2 is configured to transmit a second signal at frequency f₃.

A combiner E is configured to sum the signals and convey them to a portal where a material under test (MUT) is disposed. The MUT will normally be a material of or having an explosive composition. A receiver is configured to listen for a third frequency f₁, lower than frequencies f₂ and f₃ by way of a directional coupler and/or an amplifier.

The phenomenon that enables the method conducted by the foregoing apparatus is shown in FIG. 2. The MUT absorbs f₂ and f₃ pumped into the portal by the signal generators with a resultant cascading energy event that generates a third signal at a lower frequency f₁. If, for example, f₂ is at 3 MHz and f₃ is at 3.3 MHz, the absorption by the MUT may result in the frequencies cascading down to a lower frequency f₁ at 1 MHz. The receiver tuned to f₁ will avoid noise in returns at the original f₂ and f₃ frequencies. In other words, the apparatus and method achieves a higher single to noise ratio than would otherwise be achieved by listening for the original frequencies f₂ or f₃.

While the present invention has been described in connection with the preferred embodiments of the various figures, it is to be understood that other similar embodiments may be used or modifications and additions may be made to the described embodiment for performing the same function of the present invention without deviating there from. Therefore, the present invention should not be limited to any single embodiment, but rather construed in breadth and scope in accordance with the recitation of the appended claims.

1. A method for increasing signal to noise ratio in a Nuclear Quadrupole Resonance (NQR) system comprising:
transmitting from a first signal generator a first signal at a first frequency (f₂);
transmitting from a second signal generator a second signal at a second frequency (f3);
combining the first and second signals in a combiner;
conveying the combined first and second signals to a portal where a material under test is disposed; and
listening at a receiver for a third frequency (f₁) resulting from a cascading event in the material under test wherein the third frequency is lower than the first and second frequencies thereby avoiding noise in returns at the first and second frequencies.

2. The method of claim 1 wherein two spectral lines are generated at different frequencies (f₂, f₃) causing the cascading energy event in the material under test, such that energy is emitted from the material under test at the third frequency (f₁).

3. The method of claim 1 wherein the material under test is an explosive.

4. A system for detecting a material under test in a portal using nuclear quadrupole resonance comprising:
a first signal generator configured to transmit a first signal at a first frequency (f₂);
a second signal generator configured to transmit a second signal at a second frequency (f3);
a combiner configured to sum the first and second signals and convey them to the portal; and
a receiver tuned to listen for a third frequency f₁, lower than the first and second frequencies f₂ and f₃.

5. The system of claim 4 further comprising at least one of a directional coupler or an amplifier to convey the third signal to the receiver.

6. The system of claim 4 wherein the material under test is an explosive.

7. The method of claim 2 wherein the material under test is an explosive.

8. The system of claim 5 wherein the material under test is an explosive.
